(19) United States
(12) Patent Application Publication
(10) Pub. No.: US 2025/0293057 A1
(43) Pub. Date: Sep. 18, 2025

(54) APPARATUS FOR WAFER PROCESSING

(71) Applicant: Samsung Electronics Co., Ltd., Suwon-si (KR)

(72) Inventors: Young Chul KWON, Suwon-si (KR); Nam-Tae HEO, Suwon-si (KR)

(73) Assignee: Samsung Electronics Co., Ltd., Suwon-si (KR)

(21) Appl. No.: 19/076,267

(22) Filed: Mar. 11, 2025

(30) Foreign Application Priority Data
Mar. 12, 2024 (KR) 10-2024-0034367

(51) Int. Cl. H01L 21/67; B23K 26/06; B23K 26/38; G02B 19/00

(52) U.S. Cl. CPC H01L 21/67092; B23K 26/0648; B23K 26/38; G02B 19/0009; G02B 19/0047

(57) ABSTRACT

An apparatus for wafer processing includes a stage supporting a wafer and movable in a first direction parallel with an upper surface of the wafer; a laser light source generating a laser beam; a first optical system generating branch beams spaced apart from each other by a first distance in a second direction parallel with the upper surface and crossing the first direction, by branching the laser beam in the second direction; a second optical system generating a plurality of second branch beams spaced apart from each other in the first direction by branching the laser beam in the first direction; and an actuator adjusting the first distance. The first and second optical systems simultaneously form first and second beam regions spaced apart from each other by the first distance on the wafer in a direction parallel with the first direction as the stage moves in the first direction.

### CROSS-REFERENCE TO RELATED APPLICATION

This application claims priority from Korean Patent Application No. 10-2024-0034367 filed on Mar. 12, 2024 in the Korean Intellectual Property Office and all the benefits accruing therefrom under 35 U.S.C. 119, the contents of which in its entirety are herein incorporated by reference.

### BACKGROUND

The present disclosure relates to apparatuses for wafer processing.

After integrated circuits are formed on an active surface of a semiconductor substrate, the semiconductor substrate is cut to separate the integrated circuits into respective semiconductor chips. In general, the semiconductor substrate is mechanically cut using a sawing blade. In this way, when the semiconductor substrate is mechanically cut by mechanical cutting, there is a high possibility that defects such as chipping may occur in a semiconductor chip. Recently, as a method for reducing a physical damage to a semiconductor chip, such as chipping, methods of cutting a substrate by using a laser beam has been studied.

### SUMMARY

Some example embodiments of the present disclosure provide an apparatus for wafer processing that improves productivity.

The objects of the present disclosure are not limited to those mentioned herein and additional objects of the present disclosure, which are not mentioned herein, will be clearly understood by those skilled in the art from the following description of the present disclosure.

Some example embodiments of the present disclosure provide an apparatus for wafer processing that includes a stage that supports a wafer thereon, the stage being movable in a first direction parallel with an upper surface of the wafer; a laser light source that generates a laser beam; a plurality of optical systems that generate a plurality of branch beams based on the laser beam, the plurality of optical systems including a first optical system that generates (1_1)th and (1_2)th branch beams of the plurality of branch beams, the (1_1)th and (1_2)th branch beams being branched in a second direction and being spaced apart from each other by a first distance in the second direction, and the second direction being parallel with the upper surface of the wafer and crossing the first direction, and a second optical system that generates a plurality of second branch beams of the plurality of branch beams, the plurality of second branch beams being branched in the first direction and being spaced apart from each other in the first direction; and an actuator that moves the second optical system to adjust the first distance between the (1_1)th and (1_2)th branch beams. The plurality of optical systems simultaneously form first and second beam regions on the wafer in a direction parallel with the first direction as the stage moves in the first direction, and the first and second beam regions being spaced apart from each other by the first distance.

Some example embodiments of the present disclosure further provide an apparatus for wafer processing that includes a stage that supports a wafer thereon, the stage being movable in a first direction parallel with an upper surface of the wafer; a laser light source generating a laser beam; a first optical system that generates a plurality of first branch beams by branching the laser beam in a second direction, the plurality of first branch beams being spaced apart from each other in the second direction by a first distance, and the second direction being parallel with the upper surface of the wafer and crossing the first direction; a second optical system that generates a plurality of second branch beams by branching a first branch beam from among the plurality of first branch beams in the first direction, the plurality of second branch beams being spaced apart from each other in the first direction; a third optical system that generates a plurality of third branch beams by branching another first branch beam from among the plurality of first branch beams, the plurality of third branch beams being spaced apart from each other in the first direction; first and second actuators that respectively move the second and third optical systems to vary the first distance; a camera that measures a position of the second optical system in the first and second directions; and a horizontal distance sensor that measures a position of the third optical system in the first and second directions.

Some example embodiments of the present disclosure still further provide an apparatus for wafer processing that includes a stage that supports a wafer thereon, the stage being movable in a first direction parallel with an upper surface of the wafer; a laser light source that generates a laser beam; a first optical system that generates a plurality of first branch beams by branching the laser beam in a second direction, the plurality of first branch beams being spaced apart from each other in the second direction, and the second direction being parallel with the upper surface of the wafer and crossing the first direction; a second optical system that generates a plurality of second branch beams by branching a first branch beam from among the plurality of first branch beams in the first direction, the plurality of second branch beams being spaced apart from each other in the first direction; a third optical system that generates a plurality of third branch beams by branching another first branch beam from among the plurality of first branch beams in the first direction, the plurality of third branch beams being spaced apart from each other in the first direction; a fourth optical system that generates a plurality of fourth branch beams by branching a split portion of the another first branch beam in the first direction, the plurality of fourth branch beams being spaced apart from each other in the first direction; a first actuator that moves the second optical system to adjust a distance between the plurality of second branch beams and the plurality of third branch beams in the second direction; and a second actuator that moves the third optical system to adjust a distance between the plurality of third branch beams and the plurality of fourth branch beams in the second direction. The second, third and fourth optical systems respectively irradiate the plurality of second branch beams, the plurality of third branch beams and the plurality of fourth branch beams onto different lines in the first direction as the stage is moved in the first direction.

Details of some example embodiments are included in the detailed description and drawings.

### BRIEF DESCRIPTION OF THE DRAWINGS

The above and other aspects and features of the present disclosure will become more apparent in view of the following description of some example embodiments thereof with reference to the attached drawings, in which:

FIG. 1 is a view illustrating an apparatus for wafer processing according to some example embodiments;

FIGS. 2 and 3 are plan views illustrating the apparatus for wafer processing of FIG. 1;

FIG. 4 is a view illustrating an apparatus for wafer processing according to some example embodiments;

FIG. 5 is a plan view illustrating the apparatus for wafer processing of FIG. 4;

FIG. 6 is a view illustrating an apparatus for wafer processing according to some example embodiments;

FIG. 7 is a view illustrating an apparatus for wafer processing according to some example embodiments;

FIG. 8 is a view illustrating an apparatus for wafer processing according to some example embodiments;

FIG. 9 is a plan view illustrating the apparatus for wafer processing of FIG. 8;

FIG. 10 is a view illustrating an apparatus for wafer processing according to some example embodiments;

FIG. 11 is a plan view illustrating the apparatus for wafer processing of FIG. 10;

FIG. 12 is a view illustrating an apparatus for wafer processing according to some example embodiments; and

FIG. 13 is a view illustrating an apparatus for wafer processing according to some example embodiments.

### DETAILED DESCRIPTION

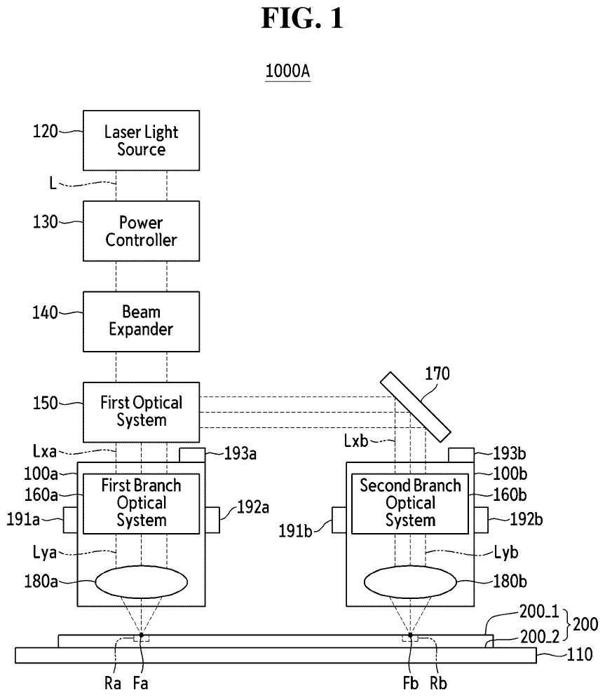

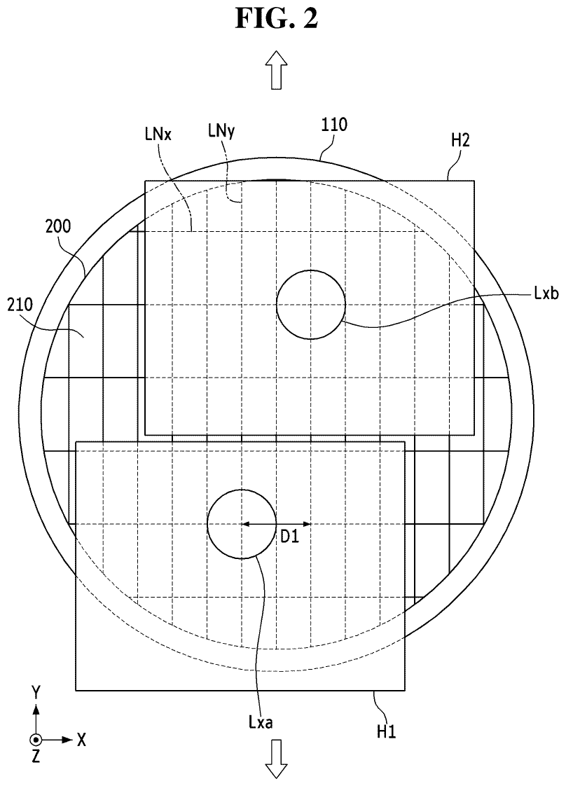

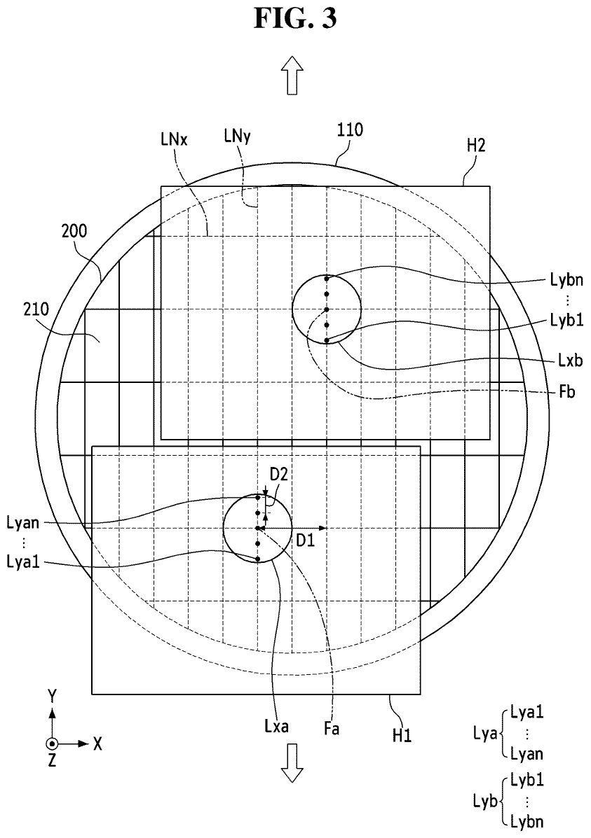

FIG. 1 is a view illustrating an apparatus for wafer processing according to some example embodiments. FIGS. 2 and 3 are plan views illustrating the apparatus for wafer processing of FIG. 1.

Referring to FIGS. 1 and 2, an apparatus 1000A for wafer processing according to some example embodiments may include a stage 110, a laser light source 120, a power controller 130, a beam expander 140, a first optical system 150, a second optical system 100a, a third optical system 100b, a camera 191a, a horizontal distance sensor 191b, height sensors 192a and 192b, and actuators 193a and 193b.

A wafer 200 may include a first surface 200_1 and a second surface 200_2, which face each other. The first surface 200_1 may be an active surface on which semiconductor elements are formed, and the second surface 200_2 may be an inactive surface. The first surface 200_1 of the wafer 200 may be extended in a first direction X and a second direction Y, which cross to be perpendicular to each other. A third direction Z may be a height direction perpendicular to each of the first and second directions X and Y

The wafer 200 may include integrated circuit regions 210, and first lines LNx and second lines LNy, wherein the first and second lines LNx and LNy separate the integrated circuit regions 210. The first lines LNx and the second lines LNy may mean scribe lines. The first lines LNx may be extended in the first direction X, and may be spaced apart from each other in the second direction Y. The second lines LNy may be extended in the second direction Y, and may be spaced apart from each other in the first direction X.

An etching process may be performed for the wafer 200 along the first lines LNx and the second lines LNy by using a laser beam L that will be described later. Therefore, grooves may be formed on the first surface 200_1 of the wafer 200. Furthermore, the integrated circuit regions 210 may be separated from each other by an etching process performed along the first lines LNx and the second lines LNy.

The wafer 200 may be loaded on the stage 110. The stage 110 may move in the first direction X and the second direction Y. The stage 110 may be rotatable on a plane including the first direction X and the second direction Y.

The apparatus 1000A for wafer processing may etch the wafer 200 by adjusting a branch direction of the laser beam L irradiated to the wafer 200. For example, as the laser beam L is branched in the first direction X and the second direction Y and the stage 110 moves in the second direction Y, beam regions Ra and Rb may be formed in the wafer 200. The etching process described above may be performed through the beam regions Ra and Rb.

Hereinafter, some example embodiments in which the stage 110 moves in the second direction Y when the laser beam L is branched in the first direction X and then branched in the second direction Y will be described by way of example.

For reference, FIG. 2 is a view illustrating laser beams in a state that the laser beam L is branched in the first direction X, and FIG. 3 is a view illustrating laser beams in a state that the laser beam L is branched in the second direction Y after being branched in the first direction X.

The laser light source 120 may generate a femtosecond laser beam. For example, the apparatus 1000A for wafer process according to some example embodiments may perform an etching process by using a laser light source having a wavelength band of 532 nm or less, but the present disclosure is not limited thereto.

The power controller 130 may provide power to the laser light source 120. The power controller 130 may be implemented by hardware, firmware, software or any combination thereof. For example, the power controller 130 may be a computing device such as a workstation computer, a desktop computer, a laptop computer, a tablet computer, etc. For example, the power controller 130 may include a memory device, such as a read only memory (ROM) or a random access memory (RAM), in which various programming instructions are stored, and a processor, such as a microprocessor, a central processing unit (CPU) and a graphics processing unit (GPU), which is configured to process the programming instructions stored in the memory device and signals provided from the outside.

The beam expander 140 may be disposed between the power controller 130 and the first optical system 150 that will be described below. The beam expander 140 may adjust a diameter of the laser beam L.

The first optical system 150 may branch the laser beam L in the first direction X. The first optical system 150 may generate a plurality of first branch beams Lxa and Lxb spaced apart from each other in the first direction X (e.g., see FIG. 2). The (1_1)th branch beam Lxa and the (1_2)th branch beam Lxb may be generated through the first optical system 150, respectively.

The (1_1)th branch beam Lxa may be transferred to a first branch optical system 160a, and the (1_2)th branch beam Lxb may be reflected through a mirror 170 and then transferred to a second branch optical system 160b. In view of a plane, the (1_1)th branch beam Lxa and the (1_2)th branch beam Lxb may be spaced apart from each other in the first direction X by a first distance D1 (e.g., see FIG. 2). The first distance D1 between the (1_1)th branch beam Lxa and the (1_2)th branch beam Lxb in the first direction X may be ‘n’ times a length of one integrated circuit region 210 in the first direction X. In some example embodiments, ‘n’ may be a natural number of 1 or more.

The second optical system 100a may branch the laser beam L in the second direction Y to generate a plurality of second branch beams Lya spaced apart from each other in the second direction Y (e.g., see FIG. 3). The second optical system 100a may include a first branch optical system 160a and a first lens 180a.

The first branch optical system 160a may branch the (1_1)th branch beam Lxa in the second direction Y. The (2_1)th and (2_n)th branch beams Lya: Lya1 to Lyan may be generated through the first branch optical system 160a, respectively. In view of a plane, the (2_1)th and (2_n)th branch beams Lya: Lya1 to Lyan may be spaced apart from each other in the second direction Y by a second distance D2 (e.g., see FIG. 2).

The first lens 180a may generate a first beam region Ra on the wafer 200 by condensing the (2_1)th and (2_n)th branch beams Lya: Lya1 to Lyan. The first lens 180a may be, for example, an objective lens.

The laser beam may be condensed on the first surface 200_1 of the wafer 200 by the apparatus 1000A for wafer processing according to some example embodiments. That is, a first condensing point Fa may be formed on the first surface 200_1 of the wafer 200. The first beam region Ra may be generated by the laser beam condensed on the first condensing point Fa to form a groove on the first surface 200_1 of the wafer 200.

The third optical system 100b may branch the laser beam L in the second direction Y. The third optical system 100b may branch the (1_2)th branch beam Lxb received through the mirror 170 in the second direction Y. The third optical system 100b may generate a plurality of third branch beams Lyb spaced apart from each other in the second direction Y. The third optical system 100b may include a second branch optical system 160b and a second lens 180b.

The second branch optical system 160b may branch the (1_2)th branch beam Lxb in the second direction Y. The (3_1)th and (3_n)th branch beams Lyb: Lyb1 to Lybn may be generated through the second branch optical system 160b, respectively. In view of a plane, the (3_1)th and (3_n)th branch beams Lyb: Lyb1 to Lybn may be spaced apart from each other in the second direction Y by the second distance D2.

The second lens 180b may generate a second beam region Rb on the wafer 200 by condensing the (3_1)th and (3_n)th branch beams Lyb: Lyb1 to Lybn. The second lens 180b may be, for example, an objective lens.

The laser beam may be condensed on the first surface 200_1 of the wafer 200 by the apparatus 1000A for wafer processing according to some example embodiments. That is, a second condensing point Fb may be formed on the first surface 200_1 of the wafer 200. The second beam region Rb may be generated by the laser beam condensed on the second condensing point Fb to form a groove on the first surface 200_1 of the wafer 200.

For example, the first to third optical systems 150, 100a and 100b may include a polarized beam splitter (PBS) and/or diffractive optical elements (DOE), but the present disclosure is not limited thereto.

The second and third optical systems 100a and 100b may be disposed on first and second laser heads H1 and H2, respectively. In some example embodiments, the respective second and third optical systems 100a and 100b may be included in the different laser heads H1 and H2.

The first laser head H1 and the second laser head H2 may be disposed above the stage 110 to downward irradiate the laser beam toward the wafer 200 on the stage 110. In view of a plane, the first and second laser heads H1 and H2 may be spaced apart from each other in the first direction Y.

For example, as the stage 110 moves in the second direction Y, the first and second condensing points Fa and Fb, which are spaced apart from each other in the first direction X, may be formed on the wafer 200 by the first and second laser heads H1 and H2. As the stage 110 moves in the second direction Y, the first and second beam regions Ra and Rb, which are spaced apart from each other in the first direction X, may be simultaneously formed on the wafer 200 in a direction parallel with the first direction X. Therefore, the first laser head H1 and the second laser head H2 may simultaneously irradiate the laser beam onto different second lines Ly, which are spaced apart from each other in the first direction X. As a result, the time required for etching the wafer 200 may be reduced and thus productivity may be improved.

The camera 191a, the first height sensor 192a and the first actuator 193a may be included in the first laser head H1 described above. The first horizontal distance sensor 191b, the second height sensor 192b and the second actuator 193b may be included in the second laser head H2 described above.

The camera 191a may measure a position of the first laser head H1 in the first and second directions X and Y. The camera 191a may measure a position of the second optical system 100a in a horizontal direction. The camera 191a may be, for example, a vision camera.

The first horizontal distance sensor 191b may measure a position of the second laser head H2 in the first and second directions X and Y. The first horizontal distance sensor 191b may correct a position between the first and second laser heads H1 and H2 in the first and second directions X and Y. The first horizontal distance sensor 191b may measure a position of the third optical system 100b in the horizontal direction and correct a position between the second and third optical systems 100a and 100b in the horizontal direction.

In some example embodiments, the position of the third optical system 100b in the first and second directions X and Y is shown as being measured by the first horizontal distance sensor 191b rather than the camera (not shown), but is not limited thereto. In some other example embodiments, the position of the third optical system 100b in the first and second directions X and Y may be measured by a camera (not shown) similarly to the second optical system 100a.

The first height sensor 192a may measure a distance between the first surface 200_1 of the wafer 200 and the first laser head H1 in a vertical direction Z. For example, the first height sensor 192a may generate first height data by measuring the distance between the first surface 200_1 of the wafer 200 and the first laser head H1. The first height sensor 192a may determine a height at a reference position as a reference value and determine heights of other positions based on a difference from the reference value.

The second height sensor 192b may measure a distance between the first surface 200_1 of the wafer 200 and the second laser head H2 in the vertical direction Z. For example, the second height sensor 192b may generate second height data by measuring the distance between the first surface 200_1 of the wafer 200 and the second laser head H2. The second height sensor 192b may determine a height at a reference position as a reference value and determine heights of other positions based on a difference from the reference value.

The first and second actuators 193a and 193b may adjust the distance D1 of the (1_1)th and (1_2)th branch beams Lxa and Lxb in the first direction X. The first and second actuators 193a and 193b may move the first and second laser heads H1 and H2 in the first direction X, respectively. The first and second actuators 193a and 193b may vary the distance D1 between the (1_1)th and (1_2)th branch beams Lxa and Lxb in the first direction X.

The distance D1 between the (1_1)th and (1_2)th branch beams Lxa and Lxb in the first direction X is not limited to that shown in the drawing, and may be varied to a length corresponding to ‘n’ times the length of one integrated circuit region 210 in the first direction X.

Although not shown in detail, an actuator (not shown) for adjusting a height of each of the first and second laser heads H1 and H2 in the third direction Z may be included. In some example embodiments, the heights of the first and second laser heads H1 and H2 in the third direction Z may be differently adjusted by actuators (not shown).

The positions and numbers of the camera 191a, the first horizontal distance sensor 191b, the first height sensor 192a, the second height sensor 192b, the first actuator 193a and the second actuator 193b, which are described above, are not limited to those shown in the drawing.

Since the apparatus 1000A for wafer processing according to some example embodiments separately includes the laser heads H1 and H2 for each optical system, a distance between the optical systems may be ensured. Therefore, as compared with apparatuses in which the optical systems are too dense, reliability of optical characteristics may be ensured.

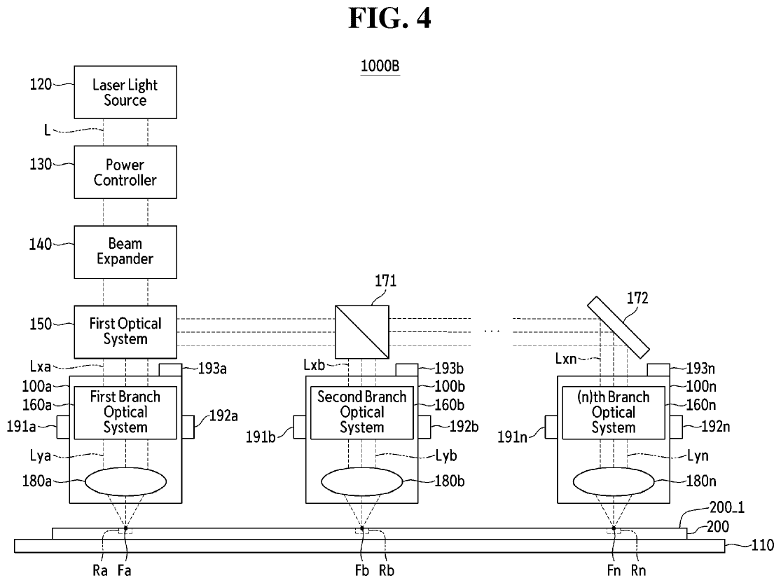

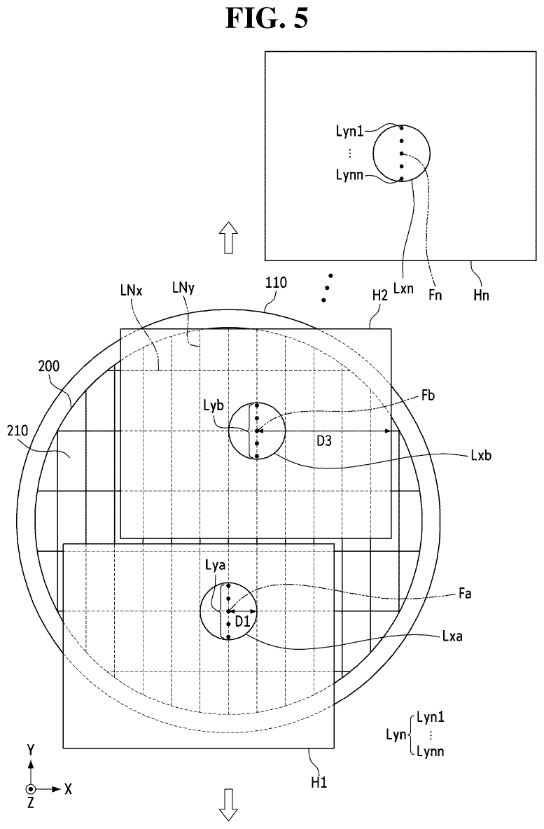

FIG. 4 is a view illustrating an apparatus for wafer processing according to some example embodiments. FIG. 5 is a plan view illustrating the apparatus for wafer processing of FIG. 4. For convenience of description, the following description will be based on differences from those described with reference to FIGS. 1 to 3.

Referring to FIGS. 4 and 5, an apparatus 1000B for wafer processing according to some example embodiments may include a plurality of laser heads H1 to Hn (n is a natural number of 3 or more) including a plurality of optical systems 100a to 100n (n is a natural number of 3 or more).

The second laser head H2 may include a third optical system 100b, a first horizontal distance sensor 191b, a second height sensor 192b and a second actuator 193b. The (n)th laser head Hn may include an (n)th optical system 100n, an (n)th horizontal distance sensor 191n, an (n)th height sensor 192n and an (n)th actuator 193n. In some example embodiments, the number of the second to (n)th horizontal distance sensors 191b to 191n may be n−1.

The description of the third optical system 100b of FIGS. 1 to 3 may be similarly applied to the (n)th optical system 100n of FIG. 4.

The third optical system 100b of FIG. 4 may be disposed between the second optical system 100a and the (n)th optical system 100n. The third optical system 100b may include a second branch optical system 160b and a second lens 180b.

The second branch optical system 160b may be disposed between the first branch optical system 160a and the (n)th branch optical system 160n.

The second lens 180b may be disposed between the first and (n)th lenses 180a and 180n, and may generate a second beam region Rb in the wafer 200. The second lens 180b may be, for example, an objective lens.

The second branch optical system 160b may branch the (1_2)th branch beam Lxb in the second direction Y by receiving the (1_2)th branch beam Lxb from a beam splitter 171. The second branch optical system 160b may generate a plurality of third branch beams Lyb spaced apart from each other in the second direction Y. The second lens 180b may condense the third branch beam Lyb to generate a second condensing point Fb on the wafer 200 and generate a second beam region Rb.

The laser beam may be condensed on the first surface 200_1 of the wafer 200 by the apparatus 1000B for wafer processing according to some example embodiments. In some example embodiments, the second condensing point Fb may be formed on the first surface 200_1 of the wafer 200. The second beam region Rb may be generated by the laser beam condensed on the second condensing point Fb to form a groove on the first surface 200_1 of the wafer 200.

The beam splitter 171 may be disposed between the first optical system 150 and the second branch optical system 160b. The beam splitter 171 may branch the beam branched from the first optical system 150 again to generate the (1_2)th branch beam Lxb. The beam splitter 171 may adjust a branch ratio so that the intensity of light condensed on the first surface 200_1 of the wafer 200 is the same for the respective condensing points Fa to Fn, but the present disclosure is not limited thereto.

A mirror 172 may be disposed between the beam splitter 171 and the (n)th branch optical system 160n. The mirror 172 may reflect the beam Lxn branched from the beam splitter 171 and transfer the reflected beam to the (n)th branch optical system 160n. The (n)th branch optical system 160n may branch the transferred beam Lxn in the second direction Y.

The (n)th branch optical system 160n may generate a plurality of (n)th branch beams Lyn: Lyn1 to Lynn spaced apart from each other in the second direction Y. The (n)th lens 180n may generate an (n)th condensing point Fn on the wafer 200 by condensing the (n)th branch beam Lyn, and may generate an (n)th beam region Rn. The (n)th lens 180n may be, for example, an objective lens.

The laser beam may be condensed on the first surface 200_1 of the wafer 200 by the apparatus 1000B for wafer processing according to some example embodiments. In some example embodiments, the (n)th condensing point Fn may be formed on the first surface 200_1 of the wafer 200. The (n)th beam region Rn may be generated by the laser beam condensed on the (n)th condensing point Fn to form a groove on the first surface 200_1 of the wafer 200.

The descriptions of the first horizontal distance sensor 191b, the second height sensor 192b and the second actuator 193b of FIG. 1 may be similarly applied to the first horizontal distance sensor 191b, the second height sensor 192b, the second actuator 193b, the (n)th horizontal distance sensor 191n, the (n)th height sensor 192n and the (n)th actuator 193n of FIG. 4.

The second and (n)th actuators 193b and 193n may adjust a distance of the (1_2)th and (1_n)th branch beams Lxb and Lxn in the first direction X. The second and (n)th actuators 193b and 193n may move the second and (n)th laser heads H2 and Hn in the first direction X, respectively. Therefore, a distance D3 between the (1_2)th and (1_n)th branch beams Lxb and Lxn in the first direction X may be adjusted.

For example, the distance D1 between the first condensing point Fa and the second condensing point Fb may be different from the distance D3 between the second condensing point Fb and the (n)th condensing point Fn based on the first direction X, but the present disclosure is not limited thereto.

The distance D3 between the (1_2)th and (1_n)th branch beams Lxb and Lxn in the first direction X is not limited to that shown in the drawing, and may be varied to a length corresponding to ‘n’ times the length of one integrated circuit region 210 in the first direction

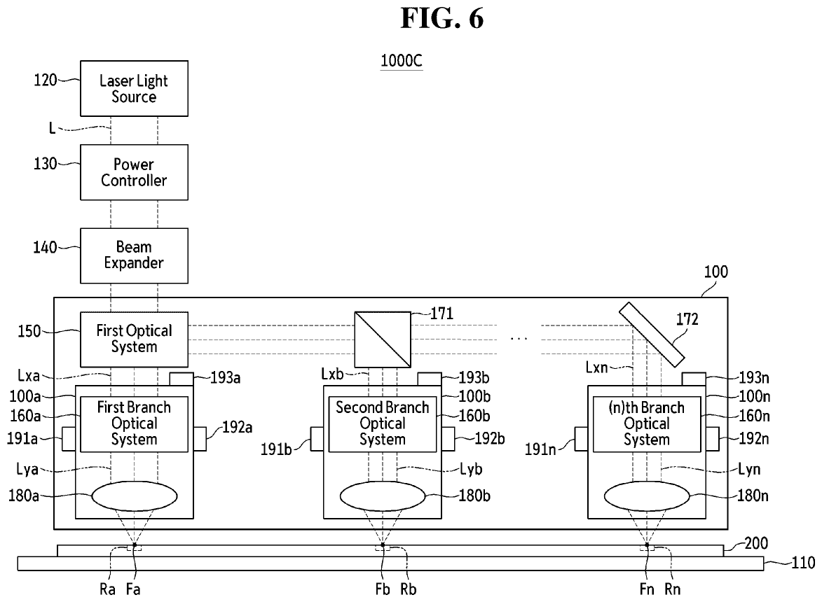

FIG. 6 is a view illustrating an apparatus for wafer processing according to some example embodiments. For convenience of description, the following description will be based on differences from those described with reference to FIGS. 1 to 5.

Referring to FIG. 6, an apparatus 1000C for wafer processing according to some example embodiments may include one laser head 100. A plurality of optical systems 100a to 100n (n is a natural number of 3 or more) may be disposed on one laser head 100.

Although not shown in detail, an actuator (not shown) for adjusting a height of the laser head 100 in the third direction Z may be disposed. In some example embodiments, the height of the laser head 100 in the third direction Z may be integrally adjusted by the actuator (not shown).

Since the apparatus 1000C for wafer processing according to some example embodiments includes only one laser head, its size may be reduced more compactly.

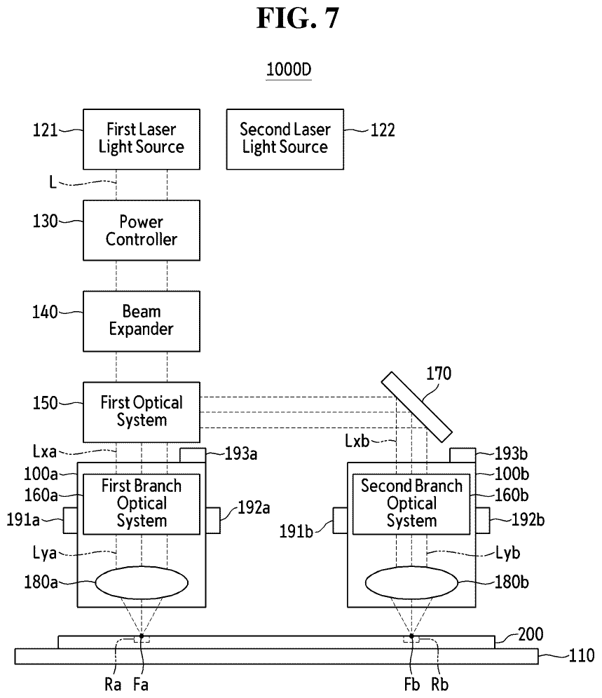

FIG. 7 is a view illustrating an apparatus for wafer processing according to some example embodiments. For convenience of description, the following description will be based on differences from those described with reference to FIG. 1.

Referring to FIG. 7, an apparatus 1000D for wafer processing according to some example embodiments may include first and second laser light sources 121 and 122. That is, unlike FIG. 1, there may be a plurality of laser light sources. The apparatus 1000D for wafer processing may further include a laser beam combiner (not shown) for combining laser beams L from the first and second laser light sources 121 and 122. The number of laser light sources is shown as two, but is not limited thereto.

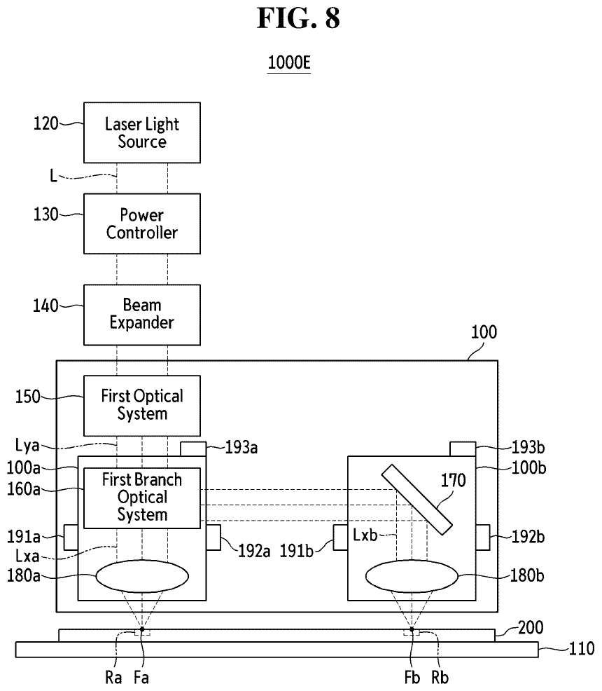

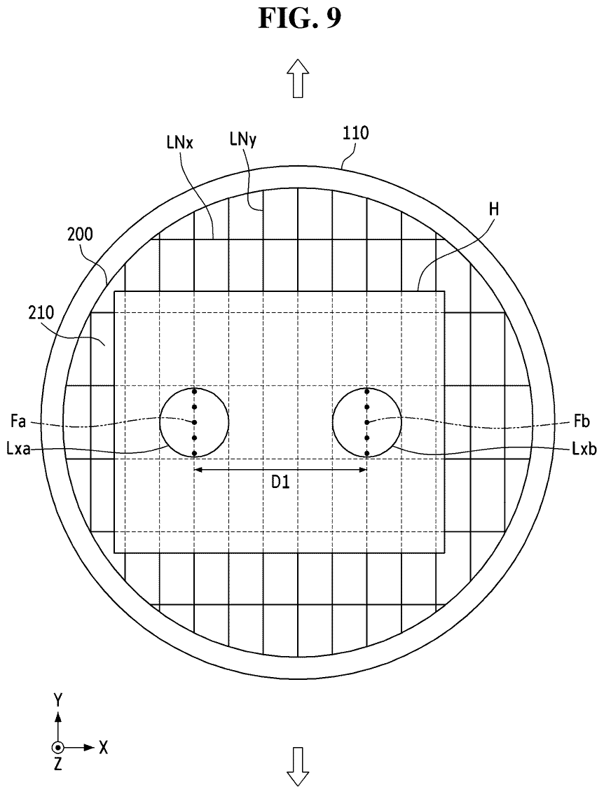

FIG. 8 is a view illustrating an apparatus for wafer processing according to some example embodiments. FIG. 9 is a plan view illustrating the apparatus for wafer processing of FIG. 8. For convenience of description, the following description will be based on differences from those described with reference to FIGS. 1 to 6.

In FIG. 8 the stage 110 moves in the second direction Y when the laser beam L is branched in the second direction Y and then branched in the first direction X, which will hereinafter be described by way of example.

Referring to FIG. 8, unlike FIGS. 1 to 7, the first optical system 150 may branch the laser beam L in the second direction Y. The first optical system 150 may generate a plurality of first branch beams Lya spaced apart from each other in the second direction Y.

Unlike FIGS. 1 to 7, the second optical system 100a may generate a plurality of second branch beams Lxa and Lxb spaced apart from each other in the first direction X by branching the plurality of first branch beams Lya in the first direction X.

The second optical system 100a may include a first branch optical system 160a and a first lens 180a.

The first branch optical system 160a may generate (1_1)th and (1_2)th branch beams Lxa and Lxb spaced apart from each other by a desired (and/or alternatively predetermined) distance D1 in the first direction X by branching the plurality of second branch beams Lya in the first direction X. The first lens 180a may generate a first beam region Ra on the wafer 200 by condensing the (1_1)th branch beam Lxa.

The third optical system 100b may include a mirror 170 and a second lens 180b. The second lens 180b may generate a second beam region Rb on the wafer by condensing the (1_2)th branch beam Lxb transferred through the mirror 170.

An apparatus 1000E for wafer processing according to some example embodiments may include one laser head 100. A plurality of optical systems 150 and 100a and 100b may be disposed on one laser head 100 and compact size may be realized.

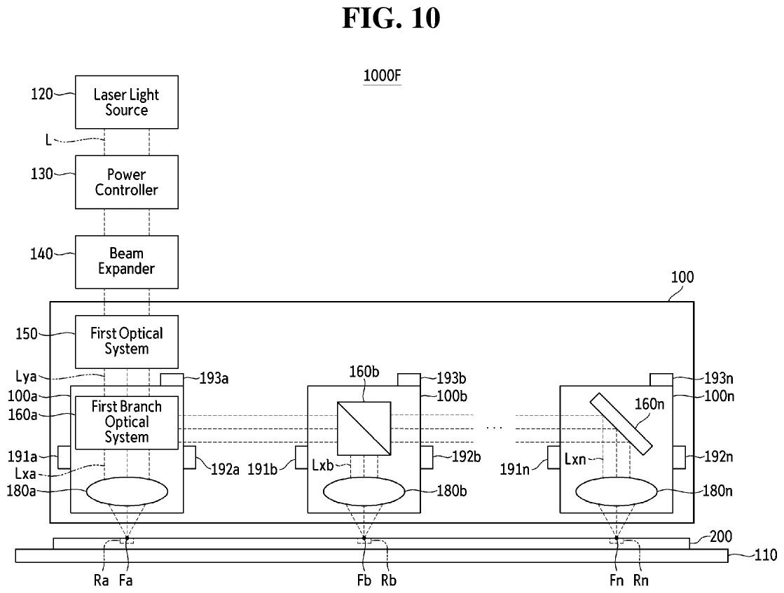

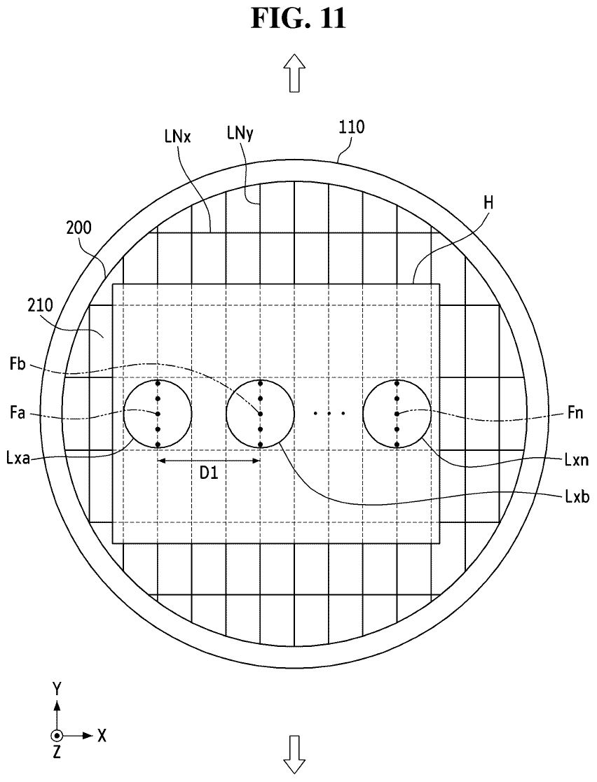

FIG. 10 is a view illustrating an apparatus for wafer processing according to some example embodiments. FIG. 11 is a plan view illustrating the apparatus for wafer processing of FIG. 10. For convenience of description, the following description will be based on differences from those described with reference to FIGS. 1 to 9.

Referring to FIG. 10, an apparatus 1000F for wafer processing according to some example embodiments may include one laser head 100 including a plurality of optical systems 100a to 100n (n is a natural number of 3 or more).

The first optical system 150 may branch the laser beam L in the second direction Y. The first optical system 150 may generate a plurality of first branch beams Lya spaced apart from each other in the second direction Y.

The second optical system 100a may branch the plurality of first branch beams Lya in the first direction X.

The third optical system 100b may be disposed between the second optical system 100a and the (n)th optical system 100n. The third optical system 100b may include a second branch optical system (e.g., beam splitter) 160b and a third lens 180b. The (n)th optical system 100n may include an (n)th branch optical system (e.g., mirror) 160n and an (n)th lens 180n.

The apparatus 1000F for wafer processing according to some example embodiments may include one laser head 100. The plurality of optical systems 100a to 100n (n is a natural number of 3 or more) may be disposed on one laser head 100 and compact size may be realized.

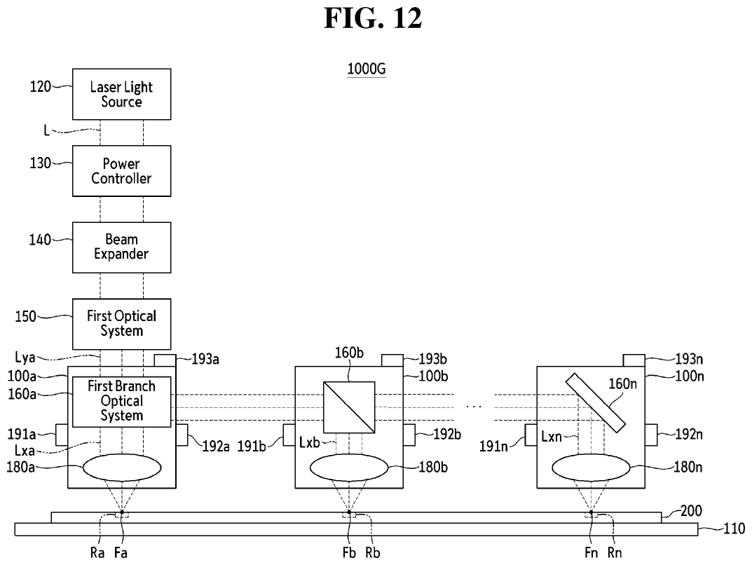

FIG. 12 is a view illustrating an apparatus for wafer processing according to some example embodiments. For convenience of description, the following description will be based on differences from those described with reference to FIG. 10.

Referring to FIG. 12, an apparatus 1000G for wafer processing according to some example embodiments may include a plurality of laser heads H1 to Hn (n is a natural number of 3 or more) respectively including a plurality of optical systems 100a to 100n (n is a natural number of 3 or more).

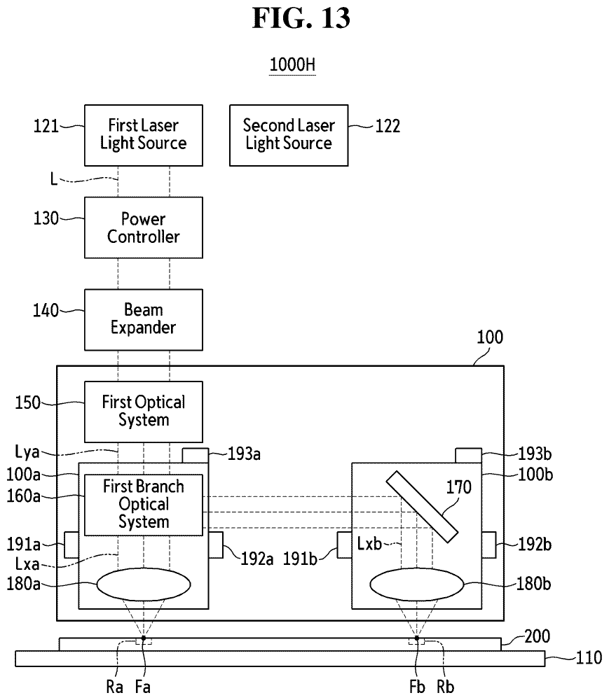

FIG. 13 is a view illustrating an apparatus for wafer processing according to some example embodiments. For convenience of description, the following description will be based on differences from those described with reference to FIG. 8.

Referring to FIG. 13, an apparatus 1000H for wafer processing according to some example embodiments may include first and second laser light sources 121 and 122. That is, unlike FIG. 8, there may be a plurality of laser light sources. The apparatus 1000H for wafer processing may further include a laser beam combiner (not shown) for combining the laser beams from the first and second laser light sources 121 and 122. The number of laser light sources is shown as two, but is not limited thereto.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

Although some example embodiments of the present disclosure have been described with reference to the accompanying drawings, it will be apparent to those skilled in the art that the present disclosure may be manufactured in various forms without being limited to the above-described some example embodiments and may be embodied in other specific forms without departing from the inventive concepts. Thus, the above some example embodiments are to be considered in all respects as illustrative and not restrictive.

What is claimed is:

1. An apparatus for wafer processing, the apparatus comprising:
a stage configured to support a wafer thereon, the stage being configured to be movable in a first direction parallel with an upper surface of the wafer;
a laser light source configured to generate a laser beam;
a plurality of optical systems configured to generate a plurality of branch beams based on the laser beam,
the plurality of optical systems comprising
a first optical system configured to generate (1_1)th and (1_2)th branch beams of the plurality of branch beams, the (1_1)th and (1_2)th branch beams being branched in a second direction and being spaced apart from each other by a first distance in the second direction, and the second direction being parallel with the upper surface of the wafer and crossing the first direction, and
a second optical system configured to generate a plurality of second branch beams of the plurality of branch beams, the plurality of second branch beams being branched in the first direction and being spaced apart from each other in the first direction; and
an actuator configured to move the second optical system to adjust the first distance between the (1_1)th and (1_2)th branch beams,
wherein the plurality of optical systems are configured to simultaneously form first and second beam regions on the wafer based on the plurality of branch beams, the first and second beam regions being formed in a direction parallel with the first direction as the stage moves in the first direction, and the first and second beam regions being spaced apart from each other by the first distance.

2. The apparatus of claim 1, wherein the second optical system includes
a first branch optical system configured to generate the plurality of second branch beams by branching the (1_1)th branch beam in the first direction, the plurality of second branch beams being spaced apart from each other in the first direction by a second distance; and
a first lens configured to condense the plurality of second branch beams to form the first beam region on the wafer.

3. The apparatus of claim 2, wherein the plurality of optical systems further comprises a third optical system, the third optical system including
a second branch optical system configured to generate a plurality of third branch beams of the plurality of branch beams by branching the (1_2)th branch beam in the first direction, the plurality of third branch beams being spaced apart from each other in the first direction by the second distance; and
a second lens configured to condense the plurality of third branch beams to form the second beam region on the wafer.

4. The apparatus of claim 3, wherein the second and third optical systems are on a first laser head.

5. The apparatus of claim 3, wherein the second and third optical systems are respectively on first and second laser heads.

6. The apparatus of claim 3, further comprising:
a camera configured to measure a position of the second optical system in the first and second directions; and
a horizontal distance sensor configured to measure a position of the third optical system in the first and second directions.

7. The apparatus of claim 3, wherein the plurality of optical systems further comprises a fourth optical system, the fourth optical system including
a third branch optical system configured to generate a plurality of fourth branch beams of the plurality of branch beams by branching the (1_2)th branch beam in the first direction, the plurality of fourth branch beams being spaced apart from each other in the first direction, and the second branch optical system being between the first branch optical system and the third branch optical system; and
a third lens configured to condense the plurality of fourth branch beams to form a third beam region on the wafer, the second lens being between the first and third lenses.

8. The apparatus of claim 1, wherein the first optical system includes
a first branch optical system configured to generate the (1_1)th and (1_2)th branch beams by branching the plurality of second branch beams in the second direction; and
a first lens configured to condense the (1_1)th branch beam to form the first beam region on the wafer.

9. The apparatus of claim 8, wherein the plurality of optical systems further comprises a third optical system, wherein the third optical system includes
a mirror configured to reflect the (1-2)th branch beam; and
a second lens configured to condense the (1_2)th branch beam reflected by the mirror to form the second beam region on the wafer.

10. The apparatus of claim 9, wherein the first to third optical systems are on a first laser head.

11. The apparatus of claim 9, wherein the plurality of optical systems further comprises a fourth optical system, wherein the fourth optical system includes
a second branch optical system between the first branch optical system and the mirror, the second branch optical system configured to branch the (1_2)th branch beam; and
a third lens between the first and second lenses, the third lens configured to condense the (1_2)th branch beam branched by the second branch optical system to form a third beam region on the wafer.

12. The apparatus of claim 1, further comprising:
a power controller configured to provide power to the laser light source; and
a beam expander configured to adjust a diameter of the laser beam.

13. An apparatus for wafer processing, the apparatus comprising:
a stage configured to support a wafer thereon, the stage being configured to be movable in a first direction parallel with an upper surface of the wafer;
a laser light source configured to generate a laser beam;
a first optical system configured to generate a plurality of first branch beams by branching the laser beam in a second direction, the plurality of first branch beams being spaced apart from each other in the second direction by a first distance, and the second direction being parallel with the upper surface of the wafer and crossing the first direction;
a second optical system configured to generate a plurality of second branch beams by branching a first branch beam from among the plurality of first branch beams in the first direction, the plurality of second branch beams being spaced apart from each other in the first direction;
a third optical system configured to generate a plurality of third branch beams by branching another first branch beam from among the plurality of first branch beams, the plurality of third branch beams being spaced apart from each other in the first direction;
first and second actuators configured to respectively move the second and third optical systems to vary the first distance;
a camera configured to measure a position of the second optical system in the first and second directions; and
a horizontal distance sensor configured to measure a position of the third optical system in the first and second directions.

14. The apparatus of claim 13, wherein the second and third optical systems are respectively on first and second laser heads, and
the second optical system includes a first lens configured to condense the plurality of second branch beams to generate a first beam region on the wafer.

15. The apparatus of claim 13, wherein the second and third optical systems are on a first laser head, and
the second optical system includes a first lens configured to condense the plurality of second branch beams to generate a first beam region on the wafer.

16. The apparatus of claim 13, wherein the first and second actuators are configured to move the second and third optical systems to correct positioning of the second and third optical systems based on the position of the third optical system measured by the horizontal distance sensor.

17. The apparatus of claim 13, wherein the first and second optical systems include a polarized beam splitter.

18. The apparatus of claim 13, wherein the laser light source is configured to generate a femtosecond laser beam.

19. An apparatus for wafer processing, the apparatus comprising:
a stage configured to support a wafer thereon, the stage being configured to be movable in a first direction parallel with an upper surface of the wafer;
a laser light source configured to generate a laser beam;
a first optical system configured to generate a plurality of first branch beams by branching the laser beam in a second direction, the plurality of first branch beams being spaced apart from each other in the second direction, and the second direction being parallel with the upper surface of the wafer and crossing the first direction;
a second optical system configured to generate a plurality of second branch beams by branching a first branch beam from among the plurality of first branch beams in the first direction, the plurality of second branch beams being spaced apart from each other in the first direction;
a third optical system configured to generate a plurality of third branch beams by branching another first branch beam from among the plurality of first branch beams in the first direction, the plurality of third branch beams being spaced apart from each other in the first direction;
a fourth optical system configured to generate a plurality of fourth branch beams by branching a split portion of the another first branch beam in the first direction, the plurality of fourth branch beams being spaced apart from each other in the first direction;
a first actuator configured to move the second optical system to adjust a distance between the plurality of second branch beams and the plurality of third branch beams in the second direction; and
a second actuator configured to move the third optical system to adjust a distance between the plurality of third branch beams and the plurality of fourth branch beams in the second direction,
wherein the second, third and fourth optical systems are configured to respectively irradiate the plurality of second branch beams, the plurality of third branch beams and the plurality of fourth branch beams onto different lines in the first direction as the stage is moved in the first direction.

20. The apparatus of claim 19, wherein the second, third and fourth optical systems are spaced apart from each other in the first direction in view of a plane.
